(19) United States
(12) Patent Application Publication
(10) Pub. No.: US 2016/0167948 A1
(43) Pub. Date: Jun. 16, 2016

(54) Vent Attachment System For Micro-Electromechanical Systems

(71) Applicant: W. L. Gore & Associates, Inc., Newark, DE (US)

(72) Inventors: Andrew J. Holliday, Wilmington, DE (US); William A. Kinder, Wilmington, DE (US)

(21) Appl. No.: 14/570,221

(22) Filed: Dec. 15, 2014

(51) Int. Cl. B81B 7/00; B32B 7/12; B32B 27/32; B32B 27/28; B81C 1/00; B32B 27/08

(52) U.S. Cl. CPC B81B 7/0029; B81C 1/00833; B32B 27/08; B32B 27/322; B32B 27/281; B32B 27/288; B32B 7/12; B32B 2457/00

(57) ABSTRACT

A method of installing a vent to protect an open port of a micro-electrical mechanical system (MEMS) device, the vent being of the type comprising an environmental barrier membrane attached to a carrier and the vent further being attached to a liner, the method comprising the steps of: (a) feeding the vent to a die attach machine with die ejectors and at least one of a vacuum head and a gripper head; (b) detaching the vent from said liner using the die ejectors; (c) picking up the vent with at least one of the vacuum head and the gripper head of the die attach machine; (d) disposing the vent over the open port of the MEMS device; and (e) securing the vent over the open port of the MEMS device.

### FIELD

This disclosure relates to vents for open port micro-electrical mechanical systems (“MEMS”) devices, and more particularly to an attachment system for such vents.

### BACKGROUND

The integration of mechanical elements, sensors, actuators or the like and electronics on a common silicon substrate through micro-fabrication technology is known as MEMS. Micro-electro-mechanical system sensors may be used in microphones, consumer pressure sensor applications, tire pressure monitoring systems, gas flow sensors, accelerometers, and gyroscopes.

U.S. Pat. No. 7,434,305 describes a silicon condenser microphone MEMS package including an acoustic transducer and acoustic port. The acoustic port further includes an environmental barrier such as PTFE or a sintered metal to protect the transducer from environmental elements such as sunlight, moisture, oil, dirt, and/or dust.

The barrier is generally sealed between layers of conductive or non-conductive materials using adhesive layers. The disclosed condenser microphones may be attached to the circuit board using reflow soldering. Reflow soldering is performed at relatively high temperatures. Accordingly the temperature resistance of such adhesive layers is critical. The high temperature experienced in reflow soldering conditions combined with the low mechanical strength of the barrier itself has made incorporation of environmental barriers into MEMS packages in this manner quite difficult.

A need still exists for environmental protection and pressure equalization capability in a thin form factor as required by a MEMS package. Furthermore, there is a need to manufacture small venting devices in an efficient manner. The vents array disclosed herein fulfill such needs.

### SUMMARY

The present disclosure provides a method of installing a vent to protect an open port of a micro-electrical mechanical system (MEMS) device, the vent being of the type comprising an environmental barrier membrane attached to a carrier and the vent further being attached to a liner, the method comprising the steps of: (a) feeding the vent to a die attach machine with die ejectors and at least one of a vacuum head and a gripper head; (b) detaching the vent from said liner using the die ejectors; (c) picking up the vent with at least one of the vacuum head and the gripper head of the die attach machine; (d) disposing the vent over the open port of the MEMS device; and (e) securing the vent over the open port of the MEMS device.

In various embodiments, the carrier comprises a material selected from the group consisting of PEEK and polyimide; the carrier is attached to the membrane by a pressure sensitive adhesive; the carrier is attached to the membrane by a weld; the weld is selected from a group comprising a heat weld, a sonic weld, and a laser weld; the liner comprises a material having a stiffness lower than a stiffness of the carrier; the liner comprises a dicing tape; the vent is attached to the liner by a pressure sensitive adhesive; and the membrane comprises ePTFE.

In another aspect, this disclosure provides a vent assembly for protecting an open port of a micro-electrical mechanical system (MEMS) device, the vent assembly comprising (a) an environmental barrier; (b) a carrier attached to the barrier, and (c) a liner attached to the carrier, wherein the liner comprises a material having a stiffness lower than a stiffness of the carrier.

In various embodiments, the vent assembly includes a pressure sensitive adhesive to attach the ePTFE membrane to the carrier; the vent assembly as defined in claim 10 further comprising a pressure sensitive adhesive to attach the carrier to the liner; the carrier comprises a material selected from the group consisting of PEEK and polyimide; the liner comprises a UV dicing tape; and the membrane comprises ePTFE.

### BRIEF DESCRIPTION OF THE DRAWINGS

FIG. 1 is a side view of an exemplary embodiment according to this disclosure.

FIG. 2 is a side view of steps in a die attach process according to an exemplary embodiment herein.

FIG. 3 is a side view of another exemplary embodiment according to this disclosure.

### DETAILED DESCRIPTION

This disclosure provides for the protection of an open port of a MEMS device by enabling a vent, which is an environmental barrier such as an ePTFE membrane, to act as a barrier to dust and liquid while allowing transmission of the intended signal: typically a temperature, pressure, or acoustic signal. The disclosure specifically relates to the attachment method, and more specifically to constructions that allow the vent to be attached with equipment that is readily available, and already used, by MEMS packaging companies.

Currently, adhesive vents are most commonly mounted on substrates either by hand or with something like a label applicator, which removes parts from an advancing roll and uses a vacuum head to place the parts on a substrate. The substrate is typically put in place by hand, or is introduced through an assembly line. Manual application and label applicators do not offer the accuracy or the throughput required for MEMS packaging applications.

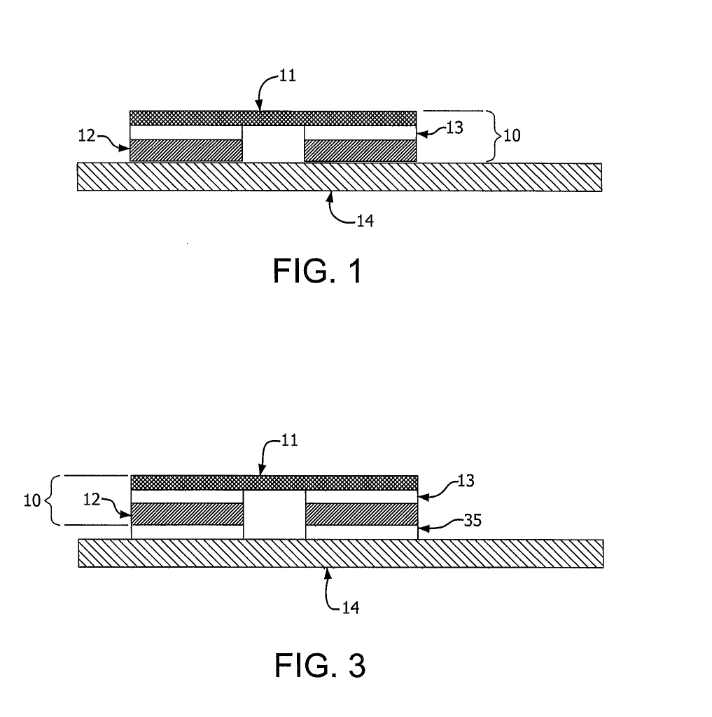

Exemplary embodiments of vent assemblies according to this disclosure will now be described in connection with the Figures. One exemplary embodiment is vent assembly 10, shown in FIG. 1. Vent assembly 10 comprises a vent 11, preferably comprising an ePTFE membrane, that has a stiff carrier 12 as its bottom layer. Stiff carrier 12 is attached to the ePTFE membrane vent 11 with an adhesive 13 in this embodiment, such as a pressure sensitive adhesive. Alternatively, it is attached with typical welding methods like heat welding, ultrasonic welding, or laser welding. Once assembled, vent 11 and carrier 12 form vent assembly 10. Vent assembly 10 is attached to a thin, low tack liner 14 with enough adhesion to keep vent assembly 10 in place during shipping, but low enough adhesion that vent assembly 10 can easily be removed. The preferred material for the low tack liner 14 is UV curable dicing tape. The UV dicing tape is initially very tacky, to allow for stability during the singulation process. After singulation, the dicing tape is be exposed to UV light, which reduces the tack and makes it easier for removal. Stiff carrier layer 12 is a material suitable for the industry; i.e., resistant to reflow temperatures, having a low CTE, and a low moisture absorption. Stiff carrier layer 12 is also significantly stiffer than the low tack liner, so that when the needles of a die-attach system press from the bottom of the liner, the vent assembly detaches reliably (described further below). It is possible to achieve this by using a thick carrier layer, but thickness is at a premium in MEMS packaging, so it is preferred that carrier 12 have as high a flexural modulus as can be achieved. PEEK is a preferred material for carrier 12 because it is a thermoplastic with a melt temperature lower than ePTFE (allowing for welding processes) and because it has a high flexural modulus and temperature resistance. Vent assembly 10 is assembled in the MEMS package using the same epoxy dispensing process that is commonly used for attaching dies and ASICs.

Alternatively, materials other than ePTFE are used, provided they have higher melt temperatures than carrier 12 and can withstand the processing temperatures. An exemplary alternative material is polyparaxylylene (PPX) and its derivatives.

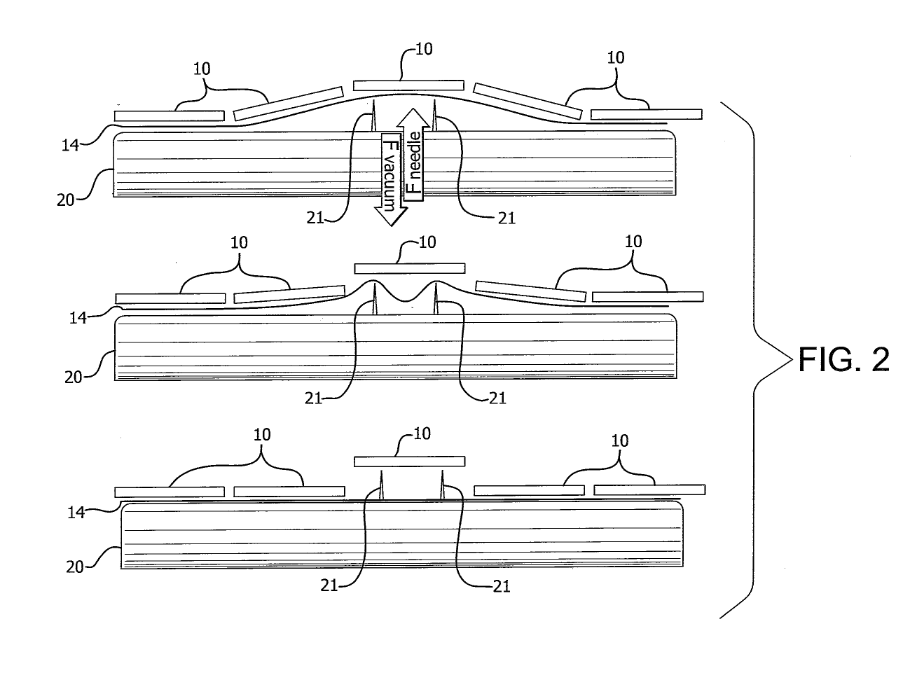

With reference to FIG. 2, vent assembly 10 is provided and introduced to die attach equipment 20 on thin, low tack liner 14. Stiff carrier layer 12 (not specifically illustrated in FIG. 2) is significantly stiffer than low tack liner 14, so that when die ejectors 21 of die attach equipment 20 press from the bottom of and penetrate liner 14, vent assembly 10 detaches reliably from liner 14. Once detached, vent assembly 10 is pickup up by a vacuum head or gripper head (not shown) of die attach equipment 20, and then disposed and secured over the open port of a MEMS device on a substrate thereof.

An alternative embodiment, which eliminates the need to use epoxy dispensing, is illustrated in FIG. 3. In this embodiment, a layer of adhesive 35 is present on the bottom of stiff carrier 12. Adhesive 35 is alternatively a pressure sensitive adhesive or a die attach film. In this embodiment, liner 14 is a thin release liner instead of a low tack liner. With a pressure sensitive adhesive for adhesive 35, vent assembly 10 is attached to the substrate of the MEMS device over an open port at room temperature using the pressure of the vacuum head which transfers the vent assembly 10 to the MEMS substrate. With a die attach film as adhesive 35, the substrate that includes the port must be heated during attachment, which is common in the industry. After attachment to the MEMS substrate, the die attach adhesive is cured in a batch process, but this step could be performed at the same time as the adhesive that attaches the die or ASIC is cured. Release liner 14 in this embodiment used to introduce vent assembly 10 is still more flexible than stiff carrier 12, by being thinner and/or having a significantly lower flexural modulus.

The disclosed vent assembly is installed either on the internal or external surface of the package, or both, and it is used in either a top or bottom port package (or both) as well.

The following examples are intended to illustrate certain embodiments of the disclosure, but are not intended to limit the scope of the appended claims.

### Examples

The following Test Method is described in connection with the examples: Axial Stiffness.

Axial Stiffness (k) in units of kg-f/cm was calculated according to the following equation:

$$k - \frac{AE}{L}$$

$$A is the cross - sectional area ( width times thickness ) of the sample in {cm}^{2}$$

$$E is the elastic modulus in kg - f \text{/} {cm}^{2}$$

$$L is the length of the sample in cm$$

The elastic modulus of the sample (25.4 mm in width, 50.8 mm in length) was measured using ASTM D882-12.

### Example 1

### Single Sided Adhesive Construction|PEEK Carrier & UV Curable Liner

A vent composite was constructed as follows: One of the two release liners from a sheet of a silicone pressure sensitive adhesive material (0.025 mm in thickness) which has two release liners on either side of the adhesive layer, was removed. The sheet of silicone adhesive was then laminated by means of pressure to a carrier layer of a film of PEEK (0.05 mm in thickness available as Product No. LS425444 from GoodFellow, USA). The PEEK side was further laminated by means of pressure to a layer of low tack adhesive with a 0.09 mm PET substrate.

Arrays of holes (diameter of 0.35 mm with center to center distance of 1.35 mm) were laser cut on the resultant laminate. Some fiducial holes were also laser cut around the perimeter of the laminate. The low tack adhesive layer was then removed from the laminate. The laminate was then placed on a layer of UV curable liner (thickness of 0.125 mm, Product No. Adwill D-485H from Lintec of America, Inc). The other release liner of the silicone pressure sensitive adhesive material sheet was then removed. An ePTFE membrane (mass/area of 1 g/m²) was then laminated to the pressure sensitive adhesive material by means of pressure to create a vent composite.

A vision system was used to identify the fiducial holes cut around the perimeter of the laminate. The vent composite was positioned such that nine arrays (1 inch by 1 inch), each comprising 400 vents (squares of length 1.3 mm each) were cut down through all the layers of the composite except the UV curable liner layer. The vent composite was then cured using the Dymax UV flood curing system for 6 seconds.

The cured vent composite was then mounted on to the ePAK hoop ring (Part No. eHR-170/186-6-OUT-X-Y) and the ring was positioned in the pick and place equipment (PP-One Manual Placer, JFP Microtechnic). Using a microscope, each vent in the array was centered over the center guide hole (2 mm in diameter) of the pepper pot having 4 needles which were spaced at a distance of 0.85 mm from each other.

The pick up tool comprised a rubber tip with four holes, 50 micron in diameter and spaced 0.76 mm apart from each other. The pick up tool was moved into place and pressed down on the vent of the array with about 50 g force. Vacuum of 55 kPa was pulled through the holes in the pick up tool as well as through the pepper pot. The pepper pot was then pneumatically pushed down, allowing the die eject needles (Small Precision Tools Inc, Part No. PUN-0.70-18 mm-15DG-25MIC) to extend by about 0.75 mm, thereby puncturing the UV curable liner layer of the vent composite and releasing the vent from the liner. The pick up tool was then moved to a placement stage consisting of a pattern of die attach epoxy. The vent was then disposed and secured over the stage.

As described in Table I below, the vent created in this example was able to be successfully picked from the liner and placed on to the placement stage. The stiffness of the liner and the carrier were measured to be 3.7 kgf/cm and 60 kgf/cm respectively.

### Example 2

### Double Sided Adhesive Construction|PEEK Carrier & LDPE Liner

A vent composite was constructed as follows: One of the two release liners from a first sheet of a silicone pressure sensitive adhesive material (0.025 mm in thickness) which has two release liners on either side of the adhesive layer, was removed. The first sheet of silicone adhesive was then laminated by means of pressure to a carrier layer of a film of PEEK (0.05 mm in thickness available as Product No. LS425444 from GoodFellow, USA).

The PEEK side was further laminated to a second sheet of a silicone pressure sensitive adhesive material (0.025 mm in thickness) having two release liners and from which one of the release liners was removed.

Arrays of holes (diameter of 0.35 mm with center to center distance of 1.35 mm) were laser cut on the resultant laminate. Some fiducial holes were also laser cut around the perimeter of the laminate. The second release layer of the second silicone adhesive sheet was then removed from the laminate.

The laminate was then placed on a layer of LDPE release liner (thickness 0.05 mm with CIS Easy Release 65 coating from Rayven Inc.). The other release liner of the first sheet of silicone pressure sensitive adhesive material was then removed. An ePTFE membrane (mass/area of 1 g/m²) was then laminated to the pressure sensitive adhesive material by means of pressure to create a vent composite.

A vision system was used to identify the fiducial holes cut around the perimeter of the laminate. The vent composite was positioned such that nine arrays (1 inch by 1 inch), each comprising 400 vents (squares of length 1.3 mm each) were cut down through all the layers of the composite except the LDPE liner layer.

The resultant vent composite was then mounted on to the ePAK hoop ring (Part No. eHR-170/186-6-OUT-X-Y) and the ring was positioned in the pick and place equipment (PP-One Manual Placer, JFP Microtechnic). Using a microscope, each vent in the array was centered over the center guide hole (2 mm in diameter) of the pepper pot having 4 needles which were spaced at a distance of 0.85 mm from each other.

The pick up tool comprised a rubber tip with four holes, 50 micron in diameter and spaced 0.76 mm apart from each other. The pick up tool was moved into place and pressed down on the vent of the array with about 50 g force. Vacuum of 55 kPa was pulled through the holes in the pick up tool as well as through the pepper pot. The pepper pot was then pneumatically pushed down, allowing the die eject needles (Small Precision Tools Inc, Part No. PUN-0.70-18 mm-15DG-25MIC) to extend by about 0.75 mm, thereby puncturing the UV curable liner layer of the vent composite and releasing the vent from the liner. The pick up tool was then moved to a placement stage. The vent was then disposed and secured over the stage.

As described in Table I below, the vent created in this example was able to be successfully picked from the liner and placed on to the placement stage. The stiffness of the liner and the carrier were measured to be 4.1 kgf/cm and 60 kgf/cm respectively.

### Comparative Example

### Double Sided Adhesive II PEEK Carrier & PET Liner

A vent composite and a vent was created according to the materials and methods described in Example 2 with the exception that a 0.05 mm PET release liner was used instead of the LDPE release liner.

As reported in Table I below, the vent created in this example was not able to be successfully picked from the liner. The stiffness of the liner and the carrier were measured to be 65 kgf/cm and 60 kgf/cm respectively.

TABLE I

| | Axial | Axial | |
|---|---|---|---|
| | Stiffness | Stiffness | |
| | Liner | Carrier | |
| Example | (kgf/cm) | (kgf/cm) | Result |
| Example 1 | 3.7 | 60 | Able to be pick and placed |
| Example 2 | 4.1 | 60 | Able to be pick and placed |
| Comparative | 65 | 60 | Not able to be picked |
| Example | | | |

What is claimed is:

1. A method of installing a vent assembly to protect an open port of a micro-electrical mechanical system (MEMS) device, said vent assembly being of the type comprising an environmental barrier membrane attached to a carrier and said vent further being attached to a liner, said method comprising the steps of:
(a) feeding said vent assembly to a die attach machine with die ejectors and at least one of a vacuum head and a gripper head;
(b) detaching said vent assembly from said liner using said die ejectors;
(c) picking up said vent assembly with at least one of said vacuum head and said gripper head of said die attach machine;
(d) disposing said vent assembly over said open port of said MEMS device; and
(e) securing said vent assembly over said open port of said MEMS device.

2. A method as defined in claim 1 wherein said carrier comprises a material selected from the group consisting of PEEK and polyimide.

3. A method as defined in claim 1 wherein said carrier is attached to said membrane by a pressure sensitive adhesive.

4. A method as defined in claim 1 wherein said carrier is attached to said membrane by a weld.

5. A method as defined in claim 4 wherein said weld is selected from a group comprising a heat weld, a sonic weld, and a laser weld.

6. A method as defined in claim 1 wherein said liner comprises a material having a stiffness lower than a stiffness of said carrier.

7. A method as defined in claim 1 wherein said liner comprises a dicing tape.

8. A method as defined in claim 1 wherein said vent assembly is attached to said liner by a pressure sensitive adhesive.

9. A method as defined in claim 1 wherein said membrane comprises ePTFE.

10. A vent assembly for protecting an open port of a micro-electrical mechanical system (MEMS) device, said vent assembly comprising:
a) an environmental barrier;
b) a carrier attached to said barrier, and
wherein said carrier is attached to a liner comprising a material having a stiffness lower than a stiffness of said carrier.

11. A vent assembly as defined in claim 10 further comprising a pressure sensitive adhesive to attach said ePTFE membrane to said carrier.

12. A vent assembly as defined in claim 10 further comprising a pressure sensitive adhesive to attach said carrier to said liner.

13. A vent assembly as defined in claim 10 wherein said carrier comprises a material selected from the group consisting of PEEK and polyimide.

14. A vent assembly as defined in claim 10 wherein said liner comprises a UV dicing tape.

15. A vent assembly as defined in claim 10 wherein said membrane comprises ePTFE.
